(19) United States
(12) Patent Application Publication
(10) Pub. No.: US 2024/0081130 A1
(43) Pub. Date: Mar. 7, 2024

(54) DISPLAY DEVICE

(71) Applicant: Japan Display Inc., Tokyo (JP)

(72) Inventor: Jun HANARI, Tokyo (JP)

(73) Assignee: Japan Display Inc., Tokyo (JP)

(21) Appl. No.: 18/461,542

(22) Filed: Sep. 6, 2023

(30) Foreign Application Priority Data
Sep. 6, 2022 (JP) 2022-141473

(51) Int. Cl. H10K 59/80; H10K 59/122

(52) U.S. Cl. CPC H10K 59/873; H10K 59/122

(57) ABSTRACT

According to one embodiment, a display device includes a lower electrode, a rib including a pixel aperture, a partition including a conductive lower portion on the rib and an upper portion protruding from a side surface of the lower portion, an organic layer covering the lower electrode through the pixel aperture, an upper electrode covering the organic layer, a first sealing layer covering a display element, a first resin layer located above the first sealing layer, and a color filter which faces the display element via the first sealing layer and the first resin layer.

### CROSS-REFERENCE TO RELATED APPLICATIONS

This application is based upon and claims the benefit of priority from Japanese Patent Application No. 2022-141473, filed Sep. 6, 2022, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer.

### BRIEF DESCRIPTION OF THE DRAWINGS

FIG. 1 is a diagram showing a configuration example of a display device according to a first embodiment.

FIG. 2 is a diagram showing an example of the layout of subpixels.

FIG. 3 is a schematic cross-sectional view of the display device along the III-III line of FIG. 2.

FIG. 4 is a schematic plan view showing shapes which can be applied to color filters and a light-shielding layer.

FIG. 5 is a schematic plan view of the display device.

FIG. 6 is a schematic plan view showing other elements provided in a surrounding area.

FIG. 7 is an enlarged view of the area surrounded by the chained frame VII in FIG. 5.

FIG. 8 is a schematic cross-sectional view of the display device along the XIII-XIII line of FIG. 7.

FIG. 9 is a schematic cross-sectional view near an end portion of a conductive layer provided in the surrounding area.

FIG. 10 is a schematic cross-sectional view showing part of the manufacturing process of the display device.

FIG. 11 is a schematic cross-sectional view showing a process following FIG. 10.

FIG. 12 is a schematic cross-sectional view showing a process following FIG. 11.

FIG. 13 is a schematic cross-sectional view showing a process following FIG. 12.

FIG. 14 is a schematic cross-sectional view showing a process following FIG. 13.

FIG. 15 is a diagram for explaining a configuration which could be applied to the light-shielding layer.

FIG. 16 is a schematic plan view of a pixel according to a first modified example.

FIG. 17 is a schematic plan view of a pixel according to a second modified example.

FIG. 18 is a schematic plan view of a pixel according to a third modified example.

FIG. 19 is a schematic cross-sectional view of the display device when a pixel includes a white subpixel.

FIG. 20 is a schematic cross-sectional view of the display device according to a fifth modified example.

FIG. 21 is a schematic cross-sectional view of the display device according to a sixth modified example.

FIG. 22 is a schematic cross-sectional view showing the structure of the display area of a display device according to a second embodiment.

FIG. 23 is a schematic cross-sectional view showing the structure of the surrounding area of the display device according to the second embodiment.

FIG. 24 is a schematic cross-sectional view showing the structure of the display area of a display device according to a third embodiment.

FIG. 25 is a schematic cross-sectional view showing the structure of the surrounding area of the display device according to the third embodiment.

FIG. 26 is a schematic cross-sectional view showing a modified example of the display device according to the third embodiment.

FIG. 27 is a schematic cross-sectional view showing the structure of the display area of a display device according to a fourth embodiment.

FIG. 28 is a schematic cross-sectional view showing the structure of the surrounding area of the display device according to the fourth embodiment.

FIG. 29 is a schematic cross-sectional view showing the structure of the display area of the display device according to a modified example of the fourth embodiment.

FIG. 30 is a schematic cross-sectional view showing the structure of the surrounding area of the display device according to a modified example of the fourth embodiment.

### DETAILED DESCRIPTION

In general, according to one embodiment, a display device comprises a lower electrode, a rib comprising a pixel aperture which overlaps the lower electrode, a partition including a conductive lower portion provided on the rib and an upper portion which protrudes from a side surface of the lower portion, an organic layer which covers the lower electrode through the pixel aperture and emits light based on application of voltage, an upper electrode which covers the organic layer and is in contact with the side surface of the lower portion, a first sealing layer which is formed of an inorganic material and covers a display element including the lower electrode, the organic layer and the upper electrode, a first resin layer located above the first sealing layer, and a color filter which faces the display element via the first sealing layer and the first resin layer.

In this configuration, the display quality of the display device can be improved.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. The third direction Z is a normal direction relative to a plane including the first direction X and the second direction Y. When various elements are viewed parallel to the plane including the first direction X and the second direction Y, the appearance is defined as a plan view.

When the position of an element located in the positive direction of the Z-axis relative to another element is referred to, the term “on” or “above” may be used. When the position of an element located on the opposite direction is referred to, the term “under” or “below” may be used. When the positional relationship between two elements is defined using the terms “on”, “above”, “under”, “below”, “face”, etc., the two elements may be directly in contact with each other, or may be spaced apart from each other as a gap or another element is interposed between them.

The display device of each embodiment is an organic electroluminescent display device comprising an organic light emitting diode (OLED) as a display element, and could be mounted on a television, a personal computer, a vehicle-mounted device, a tablet, a smartphone, a mobile phone, etc.

### First Embodiment

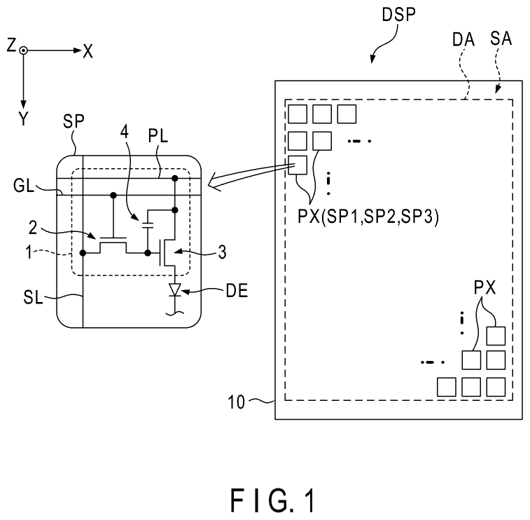

FIG. 1 is a diagram showing a configuration example of a display device DSP according to a first embodiment. The display device DSP comprises a display area DA which displays an image and a surrounding area SA around the display area DA on an insulating first substrate 10. The first substrate 10 may be glass or a resinous film having flexibility.

In the present embodiment, the first substrate 10 is rectangular as seen in plan view. It should be noted that the shape of the first substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes a red subpixel SP1, a green subpixel SP2 and a blue subpixel SP3. Each pixel PX may consist of two subpixels SP or four or more subpixels SP.

Each subpixel SP comprises a pixel circuit 1 and a display element DE driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element DE. The display element DE is an organic light emitting diode (OLED) as a light emitting element.

It should be noted that the configuration of the pixel circuit 1 is not limited to the example shown in the figure. For example, the pixel circuit 1 may comprise more thin-film transistors and capacitors.

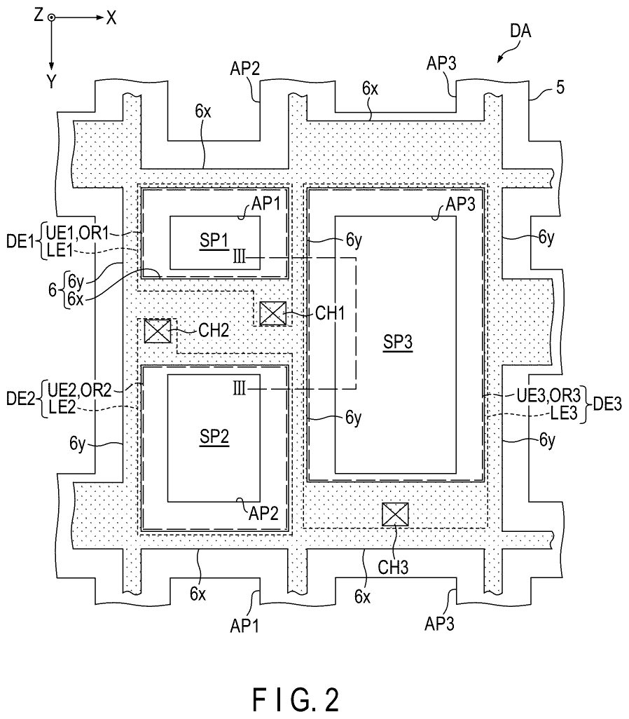

FIG. 2 is a diagram showing an example of the layout of subpixels SP1, SP2 and SP3. In the example of FIG. 2, subpixels SP1 and SP2 are arranged in the second direction Y. Further, each of subpixels SP1 and SP2 is adjacent to subpixel SP3 in the first direction X.

When subpixels SP1, SP2 and SP3 are provided in line with this layout, in the display area DA, a column in which subpixels SP1 and SP2 are alternately provided in the second direction Y and a column in which a plurality of subpixels SP3 are repeatedly provided in the second direction Y are formed. These columns are alternately arranged in the first direction X.

A rib 5 and a partition 6 are provided in the display area DA. The rib 5 comprises pixel apertures AP1, AP2 and AP3 in subpixels SP1, SP2 and SP3, respectively. In the example of FIG. 2, the pixel aperture AP2 is larger than the pixel aperture AP1. The pixel aperture AP3 is larger than the pixel aperture AP2.

The partition 6 is provided in the boundary between adjacent subpixels SP and overlaps the rib 5 as seen in plan view. The partition 6 comprises a plurality of first partitions 6x extending in the first direction X and a plurality of second partitions 6y extending in the second direction Y. The first partitions 6x are provided between the pixel apertures AP1 and AP2 which are adjacent to each other in the second direction Y and between two pixel apertures AP3 which are adjacent to each other in the second direction Y. Each second partition 6y is provided between the pixel apertures AP1 and AP3 which are adjacent to each other in the first direction X and between the pixel apertures AP2 and AP3 which are adjacent to each other in the first direction X.

In the example of FIG. 2, the first partitions 6x and the second partitions 6y are connected to each other. In this configuration, the partition 6 has a grating shape surrounding the pixel apertures AP1, AP2 and AP3 as a whole. In other words, the partition 6 comprises apertures in subpixels SP1, SP2 and SP3 in a manner similar to that of the rib 5.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

The lower electrode LE1, the upper electrode UE1 and the organic layer OR1 constitute the display element DE1 of subpixel SP1. The lower electrode LE2, the upper electrode UE2 and the organic layer OR2 constitute the display element DE2 of subpixel SP2. The lower electrode LE3, the upper electrode UE3 and the organic layer OR3 constitute the display element DE3 of subpixel SP3.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the contact holes CH1 and CH2 entirely overlap the first partition 6X between the pixel apertures AP1 and AP2 which are adjacent to each other in the second direction Y. The contact hole CH3 entirely overlaps the first partition 6x between two pixel apertures AP3 which are adjacent to each other in the second direction Y. As another example, at least part of the contact hole CH1, CH2 or CH3 may not overlap the first partition 6x.

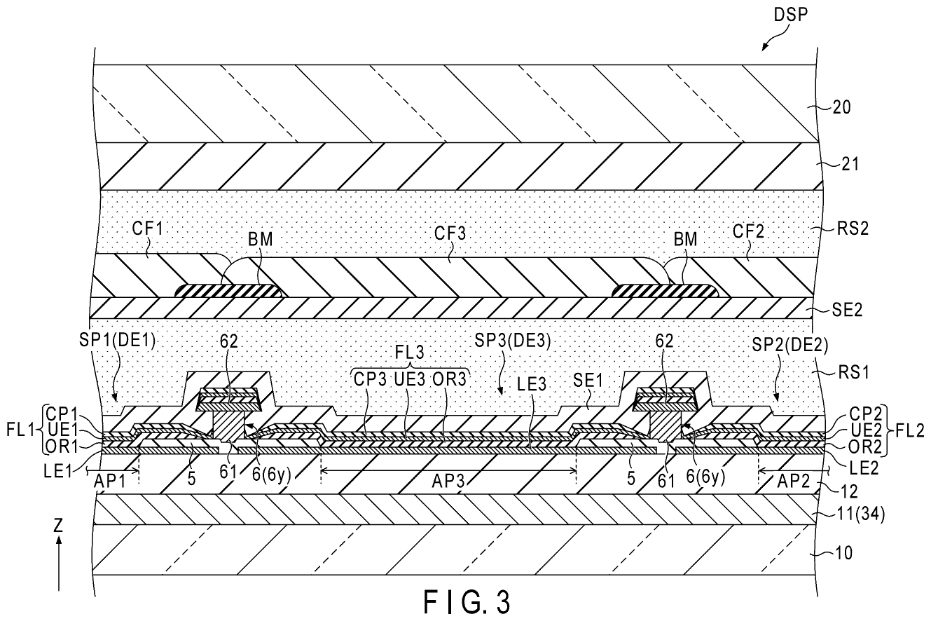

FIG. 3 is a schematic cross-sectional view of the display device DSP along the III-III line of FIG. 2. A circuit layer 11 is provided on the first substrate 10 described above. The circuit layer 11 includes various circuits and lines such as the pixel circuit 1, scanning line GL, signal line SL and power line PL shown in FIG. 1. The circuit layer 11 also includes an organic insulating layer 34 as described later. It should be noted that the illustration of the detailed layer configuration of the circuit layer 11 is omitted in FIG. 3.

The circuit layer 11 is covered with an organic insulating layer 12. The organic insulating layer 12 functions as a planarization film which planarizes the irregularities formed by the circuit layer 11. Although not shown in the section of FIG. 3, the contact holes CH1, CH2 and CH3 described above are provided in the organic insulating layer 12.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5.

The partition 6 includes a conductive lower portion 61 provided on the rib 5 and an upper portion 62 provided on the lower portion 61. The upper portion 62 has a width greater than that of the lower portion 61. By this configuration, in FIG. 3, the both end portions of the upper portion 62 protrude relative to the side surfaces of the lower portion 61. This shape of the partition 6 is called an overhang shape.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. Each of the upper electrodes UE1, UE2 and UE3 is configured such that at least part of it is in contact with the lower portion 61.

In the example of FIG. 3, a cap layer CP1 is provided above the organic layer OR1. A cap layer CP2 is provided above the organic layer OR2. A cap layer CP3 is provided above the organic layer OR3. The cap layers CP1, CP2 and CP3 adjust the optical property of the light emitted from the organic layers OR1, OR2 and OR3, respectively.

For example, the organic layers OR1, OR2 and OR3 are formed for at least the entire display area DA by the same evaporation process. The upper electrodes UE1, UE2 and UE3 are formed for at least the entire display area DA by the same evaporation process. The cap layers CP1, CP2 and CP3 are formed for at least the entire display area DA by the same evaporation process. The organic layers, upper electrodes and cap layers which are formed by vapor deposition in this manner are divided by the partition 6 having an overhang shape. These organic layers, upper electrodes and cap layers are also formed on the upper portion 62 of the partition 6.

In the following explanation, a stacked layer body including the organic layer OR1, the upper electrode UE1 and the cap layer CP1 is called a thin film FL1. A stacked layer body including the organic layer OR2, the upper electrode UE2 and the cap layer CP2 is called a thin film FL2. A stacked layer body including the organic layer OR3, the upper electrode UE3 and the cap layer CP3 is called a thin film FL3. The thin films FL1, FL2 and FL3 are spaced apart from each other via the partition 6.

In the example of FIG. 3, the thin films FL1, FL2 and FL3 and the partition 6 are continuously covered with a first sealing layer SE1. The first sealing layer SE1 is covered with a first resin layer RS1. The first resin layer RS1 is covered with a second sealing layer SE2.

In the present embodiment, the display device DSP comprises color filters CF1, CF2 and CF3 and a light-shielding layer BM. In the example of FIG. 3, the color filters CF1, CF2 and CF3 and the light-shielding layer BM are provided on the second sealing layer SE2.

The color filter CF1 faces the display element DE1 via the first sealing layer SE1, the first resin layer RS1 and the second sealing layer SE2. The color filter CF2 faces the display element DE2 via the first sealing layer SE1, the first resin layer RS1 and the second sealing layer SE2. The color filter CF3 faces the display element DE3 via the first sealing layer SE1, the first resin layer RS1 and the second sealing layer SE2. In the example of FIG. 3, the end portions of the color filters CF1 and CF3 are in contact with each other, and the end portions of the color filters CF2 and CF3 are in contact with each other.

The light-shielding layer BM is located in the boundary of two adjacent color filters of the color filters CF1, CF2 and CF3 and faces the partition 6. In the example of FIG. 3, the width of the light-shielding layer BM is greater than that of the partition 6. However, the configuration is not limited to this example.

The color filters CF1, CF2 and CF3 are covered with a second resin layer RS2. The first sealing layer SE1, the second sealing layer SE2, the first resin layer RS1 and the second resin layer RS2 are continuously provided at least in the entire display area DA and partly extend to the surrounding area SA.

The display device DSP may further comprise a second substrate 20 provided on the second resin layer RS2. The second substrate 20 is attached to the second resin layer RS2 by, for example, a transparent adhesive layer 21. For the adhesive layer 21, for example, an optical clear adhesive (OCA) can be used. For example, the second substrate 20 includes an optical element such as a polarizer, a protective film, a cover glass or a touchpanel.

The organic insulating layer 12 is formed of an organic insulating material. Each of the rib 5, the first sealing layer SE1 and the second sealing layer SE2 is formed of, for example, an inorganic material such as silicon nitride (SiNx). Each of the rib 5, the first sealing layer SE1 and the second sealing layer SE2 may be formed of silicon oxide (SiOx) or silicon oxynitride (SiON) or may be a stacked layer body consisting of at least two of a silicon nitride layer, a silicon oxide layer and a silicon oxynitride layer. Each of the first resin layer RS1 and the second resin layer RS2 is formed of a resinous material (organic insulating material) such as acrylic resin.

Each of the lower electrodes LE1, LE2 and LE3 comprises an intermediate layer formed of, for example, silver (Ag), and a pair of conductive oxide layers covering the upper and lower surfaces of the intermediate layer. Each conductive oxide layer may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

For example, each of the organic layers OR1, OR2 and OR3 comprises a multilayer structure consisting of a hole injection layer, a hole transport layer, an electron blocking layer, a light emitting layer, a hole blocking layer, an electron transport layer and an electron injection layer.

Each of the cap layers CP1, CP2 and CP3 is formed of, for example, a multilayer body of a plurality of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE1, UE2 and UE3 and are also different from the material of the first sealing layer SE1. It should be noted that at least one of the cap layers CP1, CP2 and CP3 may be omitted.

The lower portion 61 of the partition 6 is formed of, for example, aluminum (Al). The lower portion 61 may be formed of an aluminum alloy such as an aluminum-neodymium alloy (AlNd) or may comprise a multilayer structure consisting of an aluminum layer and an aluminum alloy layer. Further, the lower portion 61 may comprise a thin film formed of a metal material different from aluminum and an aluminum alloy under the aluminum layer or the aluminum alloy layer. This thin film can be formed of, for example, molybdenum (Mo).

For example, the upper portion 62 of the partition 6 comprises a multilayer structure consisting of a thin film formed of a metal material such as titanium (Ti) and a thin film formed of conductive oxide such as ITO. The upper portion 62 may comprise a single-layer structure of a metal material such as titanium. The upper portion 62 may comprise a single-layer structure formed of an inorganic insulating material.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively.

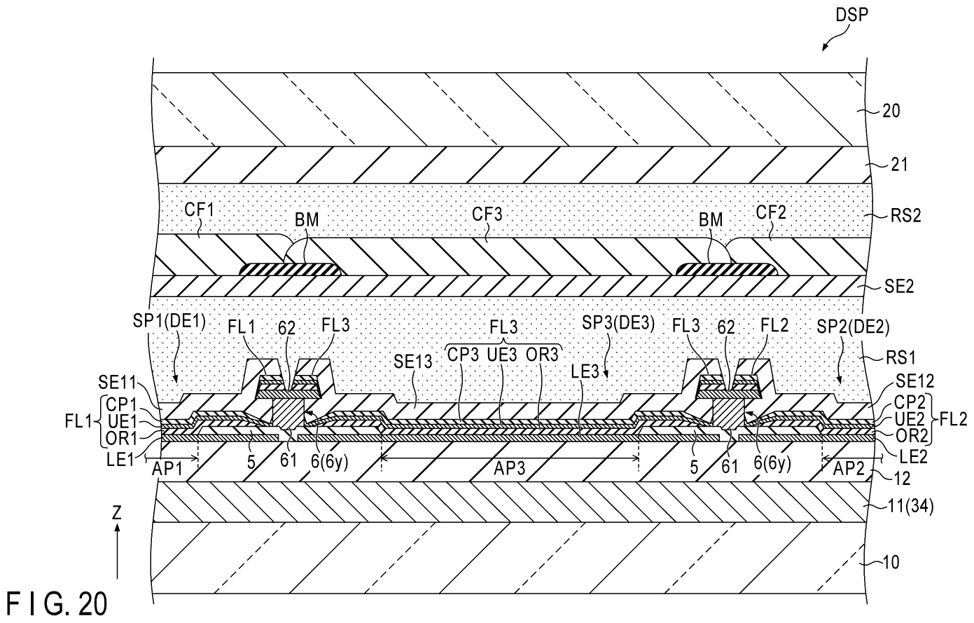

When a potential difference is formed between the lower electrode LE1 and the upper electrode UE1, the light emitting layer of the organic layer OR1 emits light. When a potential difference is formed between the lower electrode LE2 and the upper electrode UE2, the light emitting layer of the organic layer OR2 emits light. When a potential difference is formed between the lower electrode LE3 and the upper electrode UE3, the light emitting layer of the organic layer OR3 emits light. The present embodiment assumes a case where all of the organic layers OR1, OR2 and OR3 emit white light. However, as described later with reference to FIG. 20, the organic layers OR1, OR2 and OR3 may emit light exhibiting different colors.

The color filter CF1 converts the white light emitted by the organic layer OR1 into red light. The color filter CF2 converts the white light emitted by the organic layer OR2 into green light. The color filter CF3 converts the white light emitted by the organic layer OR3 into blue light.

The color filters CF1, CF2 and CF3 can be formed of, for example, organic insulating materials containing red, green and blue coloring materials, respectively. Alternatively, each of the color filters CF1, CF2 and CF3 may comprise a layer including a quantum dot which generates light exhibiting a color corresponding to subpixel SP1, SP2 or SP3 by the excitation caused by the light emitted from the organic layer OR1, OR2 or OR3.

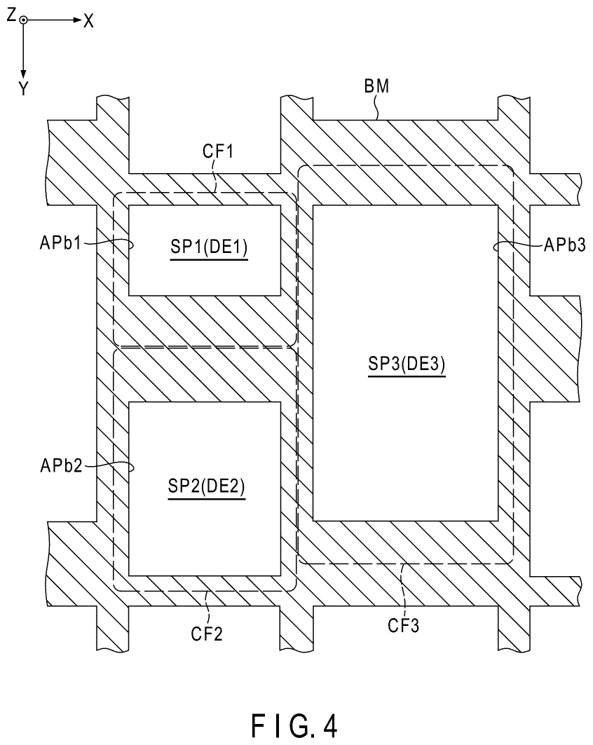

FIG. 4 is a schematic plan view showing shapes which can be applied to the color filters CF1, CF2 and CF3 and the light-shielding layer BM. In the example of FIG. 4, the light-shielding layer BM has a grating shape comprising an aperture APb1 which overlaps the display element DE1, an aperture APb2 which overlaps the display element DE2 and an aperture APb3 which overlaps the display element DE3.

The color filters CF1, CF2 and CF3 overlap the display elements DE1, DE2 and DE3, respectively. All of the peripheral portions of the color filters CF1, CF2 and CF3 overlap the light-shielding layer BM.

Although each of the color filters CF1, CF2 and CF3 has an island-like shape in FIG. 4, the shapes are not limited to this example. For example, the color filter CF3 may continuously extend over a plurality of subpixels SP3 arranged in the second direction Y.

Now, this specification explains a structure which could be applied to the surrounding area SA.

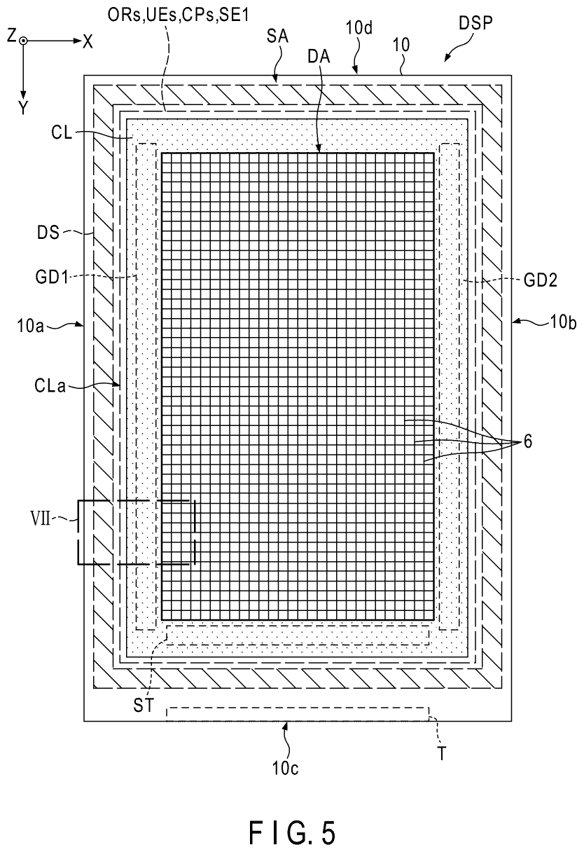

FIG. 5 is a schematic plan view of the display device DSP. The display device DSP comprises, as elements provided in the surrounding area SA, a first gate drive circuit GD1, a second gate drive circuit GD2, a selector circuit ST and a terminal portion T. The first gate drive circuit GD1, the second gate drive circuit GD2 and the selector circuit ST are examples of drive circuits which supply signals to the pixel circuits 1, and are included in the circuit layer 11 shown in FIG. 3.

The first gate drive circuit GD1 and the second gate drive circuit GD2 supply scanning signals to the scanning lines G shown in FIG. 1. For example, a flexible printed circuit is connected to the terminal portion T. The selector circuit ST supplies video signals input from the flexible printed circuit to the signal lines SL shown in FIG. 1.

The first substrate 10 comprises end portions 10a, 10b, 10c and 10d. The end portions 10a and 10b extend parallel to the second direction Y. The end portions 10c and 10d extend parallel to the first direction X.

In the example of FIG. 5, the first gate drive circuit GD1 is provided between the display area DA and the end portion 10a. The second gate drive circuit GD2 is provided between the display area DA and the end portion 10b. The selector circuit ST and the terminal portion T are provided between the display area DA and the end portion 10c.

Further, the display device DSP comprises a conductive layer CL (dotted portion) and a dam structure DS (hatched portion) in the surrounding area SA. In the example of FIG. 5, the conductive layer CL surrounds the display area DA. The dam structure DS surrounds the display area DA and the conductive layer CL. The conductive layer CL and the dam structure DS may partly overlap each other. For example, the dam structure DS functions to dam up the first resin layer RS1 and second resin layer RS2 shown in FIG. 3.

The conductive layer CL is connected to the partition 6 provided in the display area DA. The conductive layer CL overlaps the first gate drive circuit GD1, the second gate drive circuit GD2 and the selector circuit ST as seen in plan view.

It should be noted that the conductive layer CL may not necessarily have a shape surrounding the display area DA. For example, the conductive layer CL may not be provided between the display area DA and the end portion 10c and between the display area DA and the end portion 10d.

An organic layer ORs, an upper electrode UEs and a cap layer CPs are provided in the surrounding area SA. The peripheral portion of the first sealing layer SE1 is located in the surrounding area SA. The organic layer ORs is formed of the same material by the same process as the organic layers OR1, OR2 and OR3. The upper electrode UEs is formed of the same material by the same process as the upper electrodes UE1, UE2 and UE3. The cap layer CPs is formed of the same material by the same process as the cap layers CP1, CP2 and CP3.

In the example of FIG. 5, the organic layer ORs, the upper electrode UEs, the cap layer CPs and the first sealing layer SE1 overlap the conductive layer CL as seen in plan view. To the contrary, none of the organic layer ORs, the upper electrode UEs, the cap layer CPs and the first sealing layer SE1 overlaps the dam structure DS as seen in plan view.

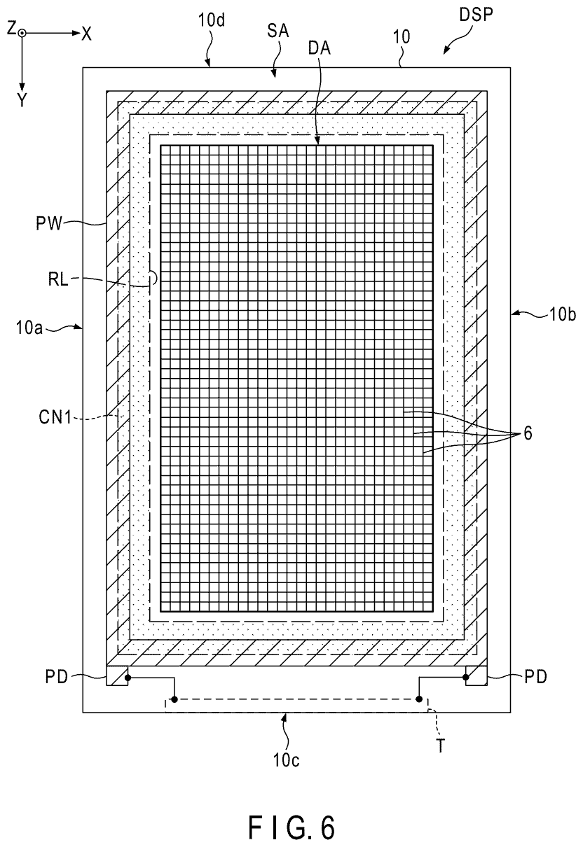

FIG. 6 is a schematic plan view showing other elements provided in the surrounding area SA. A feed line PW (hatched portion) and a relay line (RL) (dotted portion) are provided in the surrounding area SA.

In FIG. 6, the feed line PW and the relay line RL surround the display area DA. However, the configuration is not limited to this example. The feed line PW and the relay line RL partly overlap each other.

The feed line PW comprises a pair of pads PD located near the end portion 10c. These pads PD are electrically connected to the terminal portion T. Common voltage is applied to the feed line PW through the terminal portion T and each pad PD. Further, the common voltage of the feed line PW is applied to the relay line RL.

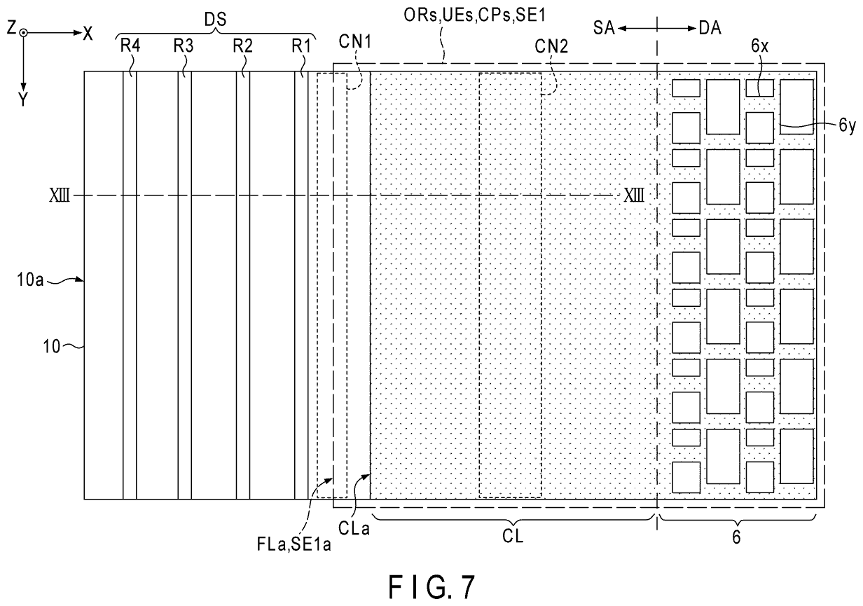

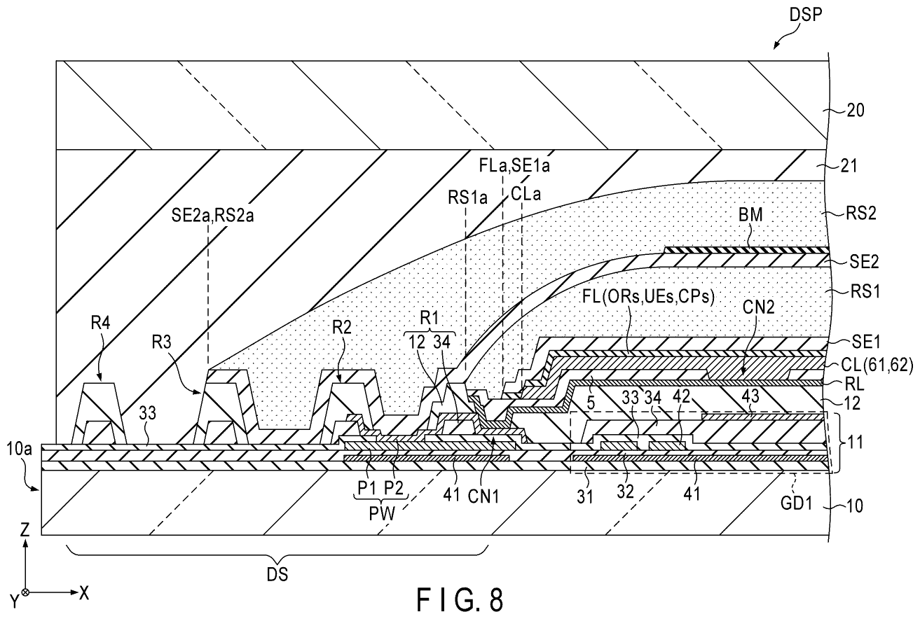

FIG. 7 is an enlarged view of the area surrounded by the chained frame VII in FIG. 5. FIG. 8 is a schematic cross-sectional view of the display device DSP along the XIII-XIII line of FIG. 7. In FIG. 7, the dotted area corresponds to the conductive layer CL and the partition 6 (the first partitions 6x and the second partitions 6y). The conductive layer CL and the partition 6 are integrally formed of the same material by the same manufacturing process.

As shown in FIG. 7 and FIG. 8, the dam structure DS comprises a plurality of protrusions R1, R2, R3 and R4. For example, each of the protrusions R1, R2, R3 and R4 has a frame shape formed along the planar shape of the dam structure DS shown in FIG. 5. In other words, the protrusion R1 surrounds the display area DA. The protrusion R2 surrounds the protrusion R1. The protrusion R3 surrounds the protrusion R2. The protrusion R4 surrounds the protrusion R3. It should be noted that the number of protrusions provided in the dam structure DS is not limited to four, and may be three or less, or five or more.

In the example of FIG. 8, the circuit layer 11 comprises inorganic insulating layers 31, 32 and 33, the organic insulating layer 34, and metal layers 41, 42 and 43. The inorganic insulating layer 31 covers the first substrate 10. The metal layer 41 is provided on the inorganic insulating layer 31 and is covered with the inorganic insulating layer 32. The metal layer 42 is provided on the inorganic insulating layer 32 and is covered with the inorganic insulating layer 33. The organic insulating layer 34 is provided on the inorganic insulating layer 33. The metal layer 43 is provided on the organic insulating layer 34 and is covered with the organic insulating layer 12.

Each of the inorganic insulating layers 31, 32 and 33 is formed of, for example, an inorganic material such as silicon nitride or silicon oxide. For example, each of the metal layers 41, 42 and 43 comprises a single-layer structure of a metal material such as molybdenum (Mo), tungsten (W), molybdenum tungsten alloy (MoW), aluminum (Al) or copper (Cu), or a multilayer structure of these metal materials.

The first gate drive circuit GD1 consists of the metal layers 41, 42 and 43 and a semiconductor layer. Similarly, the second gate drive circuit GD2 and selector circuit ST shown in FIG. 5 and the pixel circuit 1 shown in FIG. 1 consist of the metal layers 41, 42 and 43 and a semiconductor layer. The scanning line GL shown in FIG. 1 consists of the metal layer 41. The signal line SL shown in FIG. 1 consists of the metal layer 42.

The protrusions R1, R2, R3 and R4 are provided on the inorganic insulating layer 33. The rib 5 is provided in the surrounding area SA as well. In the example of FIG. 8, the rib 5 is not provided in the dam structure DS.

In the example of FIG. 8, each of the protrusions R1, R2, R3 and R4 includes a portion formed of the organic insulating layer 34 and a portion formed of the organic insulating layer 12. The portion formed of the organic insulating layer 12 covers the portion formed of the organic insulating layer 34. When each of the protrusions R1, R2, R3 and R4 consists of two organic insulating layers in this manner, the heights of the protrusions R1, R2, R3 and R4 can be increased compared to a case where each of the protrusions consists of one organic insulating layer.

The conductive layer CL covers the rib 5 in the surrounding area SA. The conductive layer CL includes a lower portion 61 and an upper portion 62 in a manner similar to that of the partition 6 shown in FIG. 3. As shown in FIG. 7 and FIG. 8, the conductive layer CL does not overlap the dam structure DS. An end portion CLa of the conductive layer CL is located between the protrusion R1 and the display area DA.

In the example of FIG. 8, the feed line PW comprises a first portion P1 formed of the metal layer 42 and a second portion P2 formed of the metal layer 43. The second portion P2 is in contact with the first portion P1. For example, of the feed line PW shown in FIG. 6, the pads PD are formed of the first portion P1, and the portion which surrounds the display area DA is formed of at least the second portion P2.

The first portion P1 is located below the organic insulating layer 34 of the protrusion R1. The second portion P2 is located on the organic insulating layer 34 of the protrusion R1 and is covered with the organic insulating layer 12. In other words, in a third direction Z (the thickness direction of the first substrate 10 or the normal direction with respect to the first substrate 10), the organic insulating layer 34 of the protrusion R1 is located between the first portion P1 and the second portion P2.

The relay line RL is largely provided on the organic insulating layer 12 and is covered with the rib 5. For example, the relay line RL is formed of the same material by the same manufacturing process as the lower electrodes LE1, LE2 and LE3.

The relay line RL is connected to the feed line PW in a first contact portion CN1 and is connected to the conductive layer CL in a second contact portion CN2. By this configuration, the common voltage of the feed line PW is applied to the conductive layer CL via the relay line RL. Further, the common voltage of the conductive layer CL is applied to the partition 6 and the upper electrodes UE1, UE2 and UE3 of the display area DA.

The first contact portion CN1 is provided near the protrusion R1. In the first contact portion CN1, the relay line RL is in contact with the second portion P2 of the feed line PW. For example, the first contact portion CN1 corresponds to the area in which the feed line PW overlaps the relay line RL in the plan view of FIG. 6, and surrounds the display area DA. It should be noted that the first contact portion CN1 may be disconnected in at least one place around the display area DA.

As shown in FIG. 8, the rib 5 comprises an aperture in the second contact portion CN2. The conductive layer CL is in contact with the relay line RL through the aperture. The aperture of the rib 5 may range over the entire second contact portion CN2 shown in FIG. 7. The rib 5 may comprise a plurality of apertures dispersed in the second contact portion CN2.

As shown in FIG. 7, the second contact portion CN2 is located between the first contact portion CN1 and the display area DA in plan view. The end portion CLa of the conductive layer CL is located between the first contact portion CN1 and the second contact portion CN2 as seen in plan view.

In FIG. 7, the area in which the organic layer ORs, the upper electrode UEs, the cap layer CPs and the first sealing layer SE1 are provided is shown by chain lines. In FIG. 8, a stacked layer body including the organic layer ORs, the upper electrode UEs and the cap layer CPs is shown as a thin film FL. In practice, the upper electrode UEs covers the organic layer ORs, and the cap layer CPs covers the upper electrode UEs. The first sealing layer SE1 covers the thin film FL.

As shown in FIG. 8, the thin film FL covers the conductive layer CL. As shown in FIG. 7, the position of an end portion FLa of the thin film FL is substantially coincident with that of an end portion SE1a of the first sealing layer SE1 in plan view. The end portions FLa and SE1a are located between the dam structure DS and the display area DA. The end portions FLa and SE1a are located between the end portion CLa of the conductive layer CL and the dam structure DS. For example, the end portions FLa and SE1a overlap the first contact portion CN1 as seen in plan view.

As shown in FIG. 8, the second sealing layer SE2, the first resin layer RS1 and the second resin layer RS2 are formed in the surrounding area SA as well. The first resin layer RS1 covers the end portions FLa and SE1a. The second sealing layer SE2 entirely covers the first resin layer RS1 and also covers part of the dam structure DS. Specifically, in the example of FIG. 8, the second sealing layer SE2 covers the protrusions R1, R2 and R3 and does not cover the protrusion R4. An end portion SE2a of the second sealing layer SE2 is located on the protrusion R3. The second sealing layer SE2 is in contact with the organic insulating layers 12 of the protrusions R1, R2 and R3, of the second portion P2 of the feed line PW, the portion located between the protrusions R1 and R2, and of the inorganic insulating layer 33, the portion located between the protrusions R2 and R3.

An end portion RS1a of the first resin layer RS1 is located at a position closer to the end portion 10a of the first substrate 10 than the end portion FLa of the thin film FL and the end portion SE1a of the first sealing layer SE1. In the example of FIG. 8, the end portion RS1a is located near the protrusion R1.

The second resin layer RS2 entirely covers the second sealing layer SE2. The position of an end portion RS2a of the second resin layer RS2 is substantially coincident with that of the end portion SE2a of the second sealing layer SE2. Thus, in the example of FIG. 8, the positions of the end portion SE2a and the end portion RS2a are aligned with each other.

The light-shielding layer BM is provided in the surrounding area SA as well. In the example of FIG. 8, the light-shielding layer BM faces the conductive layer CL via the first sealing layer SE1, the first resin layer RS1 and the second sealing layer SE2. Further, the light-shielding layer BM faces the second contact portion CN2. At least one of the color filters CF1, CF2 and CF3 may be provided in the surrounding area SA and may face the second contact portion CN2.

In the example of FIG. 8, the adhesive layer 21 entirely covers the second resin layer RS2. Further, the adhesive layer 21 also covers the inorganic insulating layer 33 between the protrusions R3 and R4 and the protrusion R4.

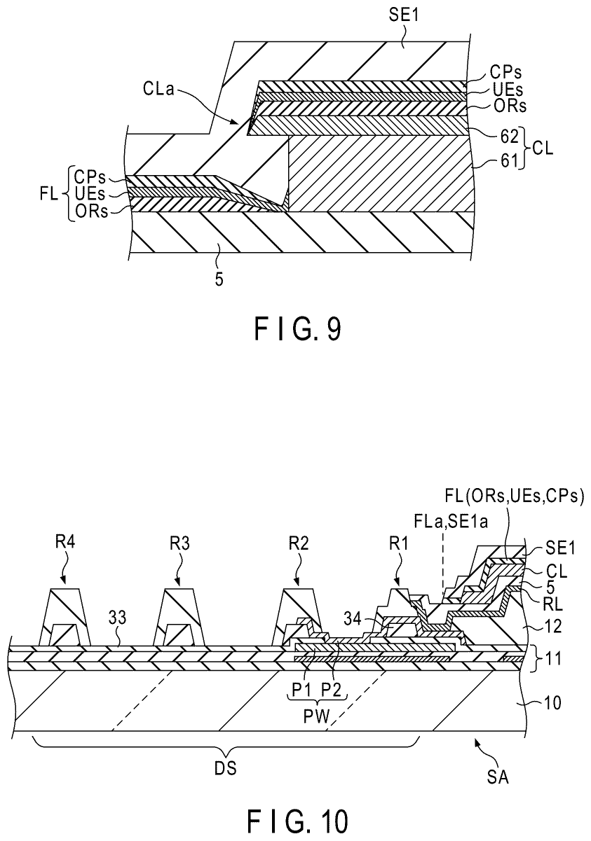

FIG. 9 is a schematic cross-sectional view near the end portion CLa of the conductive layer CL. The conductive layer CL comprises the lower portion 61 and the upper portion 62 in a manner similar to that of the partition 6 shown in FIG. 3. In the end portion CLa, the upper portion 62 protrudes relative to a side surface of the lower portion 61. In other words, the shape of the conductive layer CL in the end portion CLa is an overhang shape in a manner similar to that of the partition 6.

When the thin film FL (the organic layer ORs, the upper electrode UEs and the cap layer CPs) is formed on the conductive layer CL having this shape, as shown in FIG. 9, the thin film FL is divided in the end portion CLa. The first sealing layer SE1 covers the organic layer ORs, upper electrode UEs and cap layer CPs located on and beside the conductive layer CL and also covers a side surface of the lower portion 61.

In FIG. 7 and FIG. 8, this specification focuses attention on the structure between the display area DA and the end portion 10a of the first substrate 10. However, a similar structure can be applied to the structure between the display area DA and the end portion 10b, the structure between the display area DA and the end portion 10c and the structure between the display area DA and the end portion 10d.

Now, this specification explains the manufacturing method of the display device DSP.

FIG. 10 to FIG. 14 are schematic cross-sectional views showing part of the manufacturing process of the display device DSP. To manufacture the display device DSP, first, the circuit layer 11 including the pixel circuits 1, the gate drive circuits GD1 and GD2, the selector circuit ST and the feed line PW is formed on the first substrate 10. After the formation of the circuit layer 11, the organic insulating layer 12 is formed on the circuit layer 11.

When the organic insulating layer 12 and the organic insulating layer 34 of the circuit layer 11 are formed, these organic insulating layers 12 and 34 are patterned, and the dam structure DS including the protrusions R1, R2, R3 and R4 is formed in the surrounding area SA as shown in FIG. 10.

Subsequently, the lower electrodes LE1, LE2 and LE3 shown in FIG. 3 and the relay line RL shown in FIG. 8 are formed. On these elements, the rib 5 is formed. Further, the partition 6 and the conductive layer CL are formed.

Subsequently, the organic layers OR1, OR2, OR3 and ORs, the upper electrodes UE1, UE2, UE3 and UEs and the cap layers CP1, CP2, CP3 and CPs are formed by vapor deposition. Further, the first sealing layer SE1 is formed on these elements by, for example, chemical vapor deposition (CVD).

The thin film FL (the organic layer ORs, the upper electrode UEs and the cap layer CPs) and first sealing layer SE1 shown in FIG. 10 are patterned by dry etching and wet etching using the same mask. Thus, as shown in FIG. 10, the end portion FLa of the thin film FL is aligned with the end portion SE1a of the first sealing layer SE1.

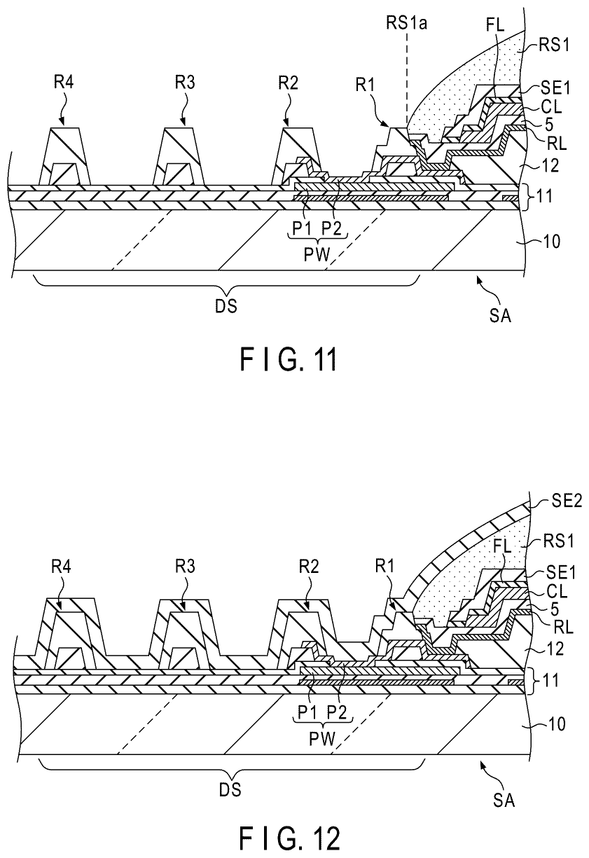

After the formation of the first sealing layer SE1, as shown in FIG. 11, the first resin layer RS1 is formed. The first resin layer RS1 is formed by, for example, an ink-jet method. The protrusions R1, R2, R3 and R4 prevent the expansion of the first resin layer RS1 before it is cured. In FIG. 11, the end portion RS1a of the first resin layer RS1 is dammed up by the protrusion R1.

After the formation of the first resin layer RS1, as shown in FIG. 12, the second sealing layer SE2 which covers the first resin layer RS1 is formed. At this point, the second sealing layer SE2 is formed in the entire first substrate 10.

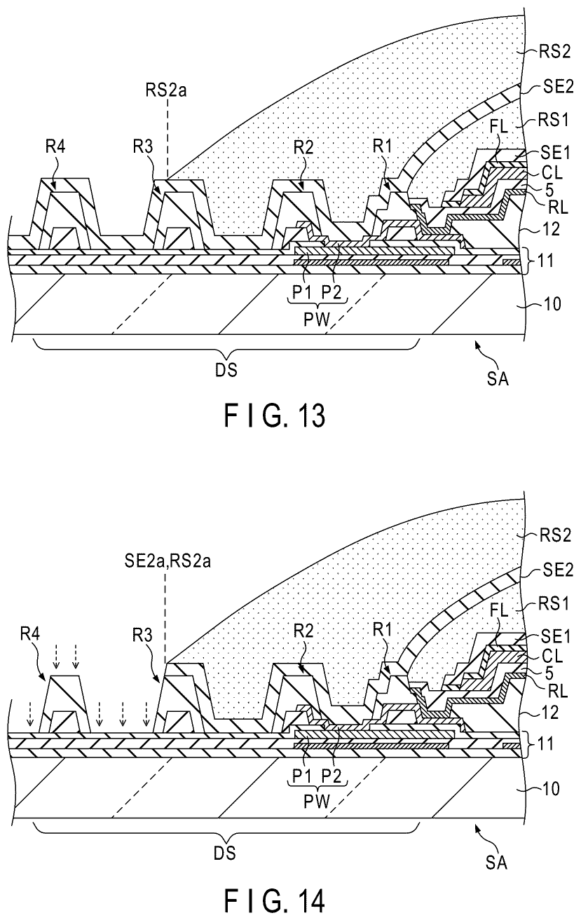

After the formation of the second sealing layer SE2, as shown in FIG. 13, the second resin layer RS2 is formed. The second resin layer RS2 is formed by, for example, an ink-jet method in a manner similar to that of the first resin layer RS1. The projections and depressions generated in the second sealing layer SE2 by the protrusions R1, R2, R3 and R4 prevent the expansion of the second resin layer RS2 before it is cured. In FIG. 13, the end portion RS2a of the second resin layer RS2 is dammed up by the protrusion R3.

Subsequently, as shown in FIG. 14, of the second sealing layer SE2, the portion exposed from the second resin layer RS2 is removed by etching. In this way, the display device DSP comprising the structure shown in FIG. 8 can be obtained. This etching is, for example, dry etching, and uses the second resin layer RS2 as a mask.

By this etching, the end portion SE2a of the second sealing layer SE2 is aligned with the end portion RS2a of the second resin layer RS2. Before the etching, as shown in FIG. 13, all of the protrusions R1, R2, R3 and R4 are covered with the second sealing layer SE2. However, after the etching, as shown in FIG. 14, part of the protrusion R3 and the protrusion R4 are exposed from the second sealing layer SE2.

According to the display device DSP of the present embodiment described above, in the structure in which the adjacent display elements DE1, DE2 and DE3 are divided by the partition 6, the color filters CF1, CF2 and CF3 facing the display elements DE1, DE2 and DE3 are provided. Further, the first resin layer RS1 is provided between the color filters CF1, CF2 and CF3 and the display elements DE1, DE2 and DE3. In this structure, the installation surface of the color filters CF1 CF2 and CF3 is planarized by the first resin layer RS1. Thus, the structure allows the formation of the color filters CF1, CF2 and CF3 having good shapes and the improvement of the display quality of the display device DSP.

Moreover, when the emission colors of subpixels SP1, SP2 and SP3 are differentiated by using the color filters CF1, CF2 and CF3 like the present embodiment, the emission colors of the display elements DE1, DE2 and DE3 can be the same as each other. In this case, the thin films FL1, FL2 and FL3 can be formed together by the same process.

If the thin films FL1, FL2 and FL3 are individually formed, there is a possibility that the rib 5 and the partition 6 are damaged as they are exposed to more etching processes. When the thin films FL1, FL2 and FL3 are formed together by the same process, this damage can be reduced. Further, as none of the end portions of the thin films FL1, FL2 and FL3 is generated on the partition 6, the planarization with the first resin layer RS1 is made easy.

In the present embodiment, as the light-shielding layer BM is provided in the boundaries of the color filters CF1, CF2 and CF3, the reflection of external light on the partition 6 and the rib 5 and the color mixture of adjacent subpixels can be prevented. When the light-shielding layer BM overlaps the second contact portion CN2 in the third direction Z in the surrounding area SA as shown in FIG. 8, the portions of the projections and depressions generated by the second contact portion CN2 can be shielded from light.

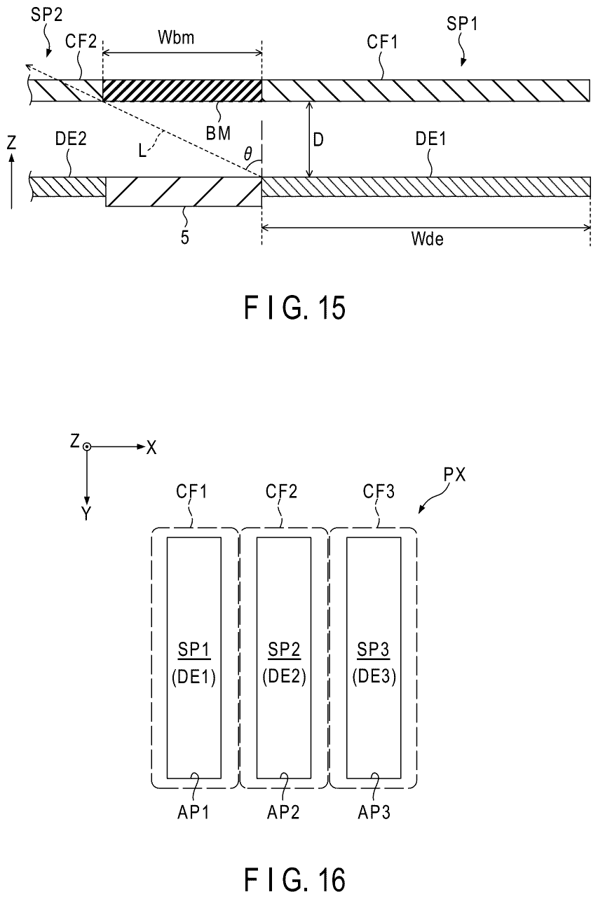

FIG. 15 is a diagram for explaining a configuration which could be applied to the light-shielding layer BM, and schematically shows the display elements DE1 and DE2, the color filters CF1 and CF2, the rib 5 and the light-shielding layer BM. In a case where it is necessary to prevent the reflection of external light on the rib 5 when the display area DA is viewed from the front side, width Wbm of the light-shielding layer BM should be desirably equal to the width of the rib 5 or greater than the width of the rib 5.

In a case where the display area DA is obliquely viewed, for example, when light L emitted by the display element DE1 passes through the color filter CF2 instead of the color filter CF1, the color mixture of subpixels SP1 and SP2 could be caused. This color mixture is more easily caused as distance D between the display elements DE1 and DE2 and the light-shielding layer BM in the third direction Z is increased. In the configuration of FIG. 3, distance D corresponds to the total thickness of the first sealing layer SE1, the first resin layer RS1 and the second sealing layer SE2.

From this point of view, for example, width Wbm should be desirably greater than or equal to four times distance D, or more desirably greater than or equal to six times distance D. By this configuration, angle θ of light for causing color mixture can be set so as to be greater than or equal to approximately 75°. In other words, when the inclination of the direction in which the user views the display area DA relative to the third direction Z is less than 75°, color mixture can be satisfactorily prevented.

The configuration disclosed in the present embodiment could be modified in various ways. Some modified examples are disclosed below.

FIG. 16 is a schematic plan view of a pixel PX according to a first modified example. In this example, subpixels SP1, SP2 and SP3 constituting the pixel PX are arranged in the first direction X. When a plurality of pixels PX each comprising this structure are arranged in the first direction X and the second direction Y, a column in which a plurality of subpixels SP1 are successively provided in the second direction Y, a column in which a plurality of subpixels SP2 are successively provided in the second direction Y and a column in which a plurality of subpixels SP3 are successively provided in the second direction Y are formed in the display area DA.

In the example of FIG. 16, the color filters CF1, CF2 and CF3 each having an island-like shape are provided. Alternatively, a color filter CF1 which is continuously formed over a plurality of subpixels SP1 arranged in the second direction Y, a color filter CF2 which is continuously formed over a plurality of subpixels SP2 arranged in the second direction Y and a color filter CF3 which is continuously formed over a plurality of subpixels SP3 arranged in the second direction Y may be provided in the display area DA.

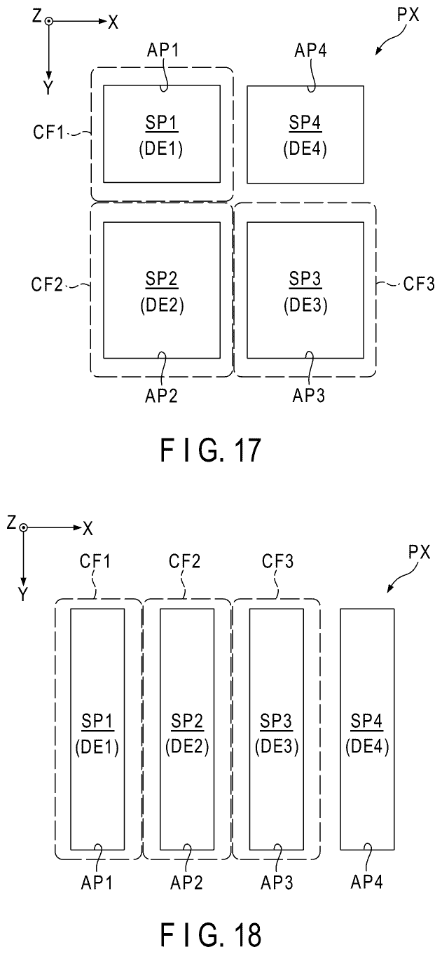

FIG. 17 is a schematic plan view of a pixel PX according to a second modified example. In this example, the pixel PX includes a white subpixel SP4 in addition to subpixels SP1, SP2 and SP3. In the example of FIG. 17, subpixel SP1 and subpixel SP4 are arranged in the first direction X, and subpixel SP2 and subpixel SP3 are arranged in the first direction X. Subpixel SP1 and subpixel SP2 are arranged in the second direction Y, and subpixel SP3 and subpixel SP4 are arranged in the second direction Y.

For example, all of the display elements DE1, DE2, DE3 and DE4 of subpixels SP1, SP2, SP3 and SP4 emit white light. Red, green and blue color filters CF1, CF2 and CF3 are provided in subpixels SP1, SP2 and SP3, respectively. To the contrary, no color filter is provided in subpixel SP4.

FIG. 18 is a schematic plan view of a pixel PX according to a third modified example. In this example, the pixel PX includes subpixels SP1, SP2, SP3 and SP4 in a manner similar to that of the second modified example. However, subpixels SP1, SP2, SP3 and SP4 are arranged in the first direction X. When a plurality of pixels PX each comprising this structure are arranged in the first direction X and the second direction Y, a column in which a plurality of subpixels SP1 are successively provided in the second direction Y, a column in which a plurality of subpixels SP2 are successively provided in the second direction Y, a column in which a plurality of subpixels SP3 are successively provided in the second direction Y and a column in which a plurality of subpixels SP4 are successively provided in the second direction Y are formed in the display area DA.

In the example of FIG. 18, the color filters CF1, CF2 and CF3 each having an island-like shape are provided. Alternatively, a color filter CF1 which is continuously formed over a plurality of subpixels SP1 arranged in the second direction Y, a color filter CF2 which is continuously formed over a plurality of subpixels SP2 arranged in the second direction Y and a color filter CF3 which is continuously formed over a plurality of subpixels SP3 arranged in the second direction Y may be provided in the display area DA.

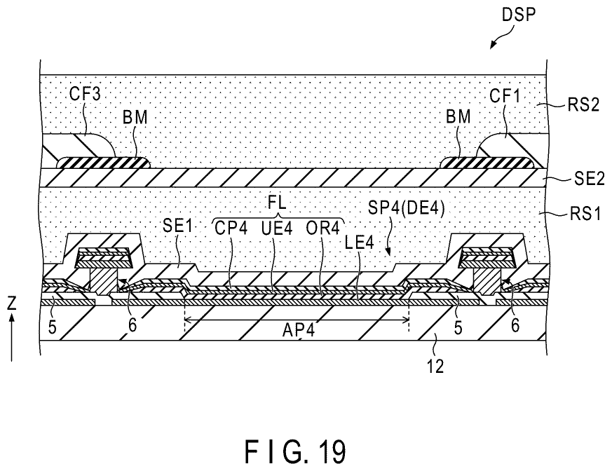

FIG. 19 is a schematic cross-sectional view of the display device DSP when a pixel PX includes subpixel SP4 like the third and fourth modified examples. In the example of this figure, no color filter is provided above the display element DE4. Thus, the second sealing layer SE2 is covered with the second resin layer RS2 above the display element DE4. In addition, the light-shielding layer BM is partly covered with the second resin layer RS2.

FIG. 20 is a schematic cross-sectional view of the display device DSP according to a fifth modified example. The display element DE1, DE2 or DE3 is not limited to a display element which emits white light as described above. This modified example assumes a case where the display elements DE1, DE2 and DE3 emit red light, green light and blue light, respectively.

To realize these display elements DE1, DE2 and DE3, the thin films FL1, FL2 and FL3 are formed by different processes. The first sealing layers SE1 which cover the thin films FL1, FL2 and FL3 are also formed by different processes. Hereinafter, the first sealing layers SE1 which cover the thin films FL1, FL2 and FL3 are called first sealing layers SE11, SE12 and SE13, respectively.

In the example of FIG. 20, each of the thin film FL1 and the thin film FL3 is partly formed on the upper portion 62 of the partition 6 between subpixels SP1 and SP3, and these portions are spaced apart from each other. In addition, the end portions of the first sealing layers SE11 and SE13 located on this upper portion 62 are spaced apart from each other.

Similarly, in the example of FIG. 20, each of the thin film FL2 and the thin film FL3 is partly formed on the upper portion 62 of the partition 6 between subpixels SP2 and SP3, and these portions are spaced apart from each other. In addition, the end portions of the first sealing layers SE12 and SE13 located on this upper portion 62 are spaced apart from each other.

The color filters CF1, CF2 and CF3 of the fifth modified example function as, for example, antireflective layers. For example, in this configuration, the reduction of energy consumption or the improvement of luminance can be realized compared with a case where a circular polarizer is provided so as to overlap the display area DA to prevent reflection.

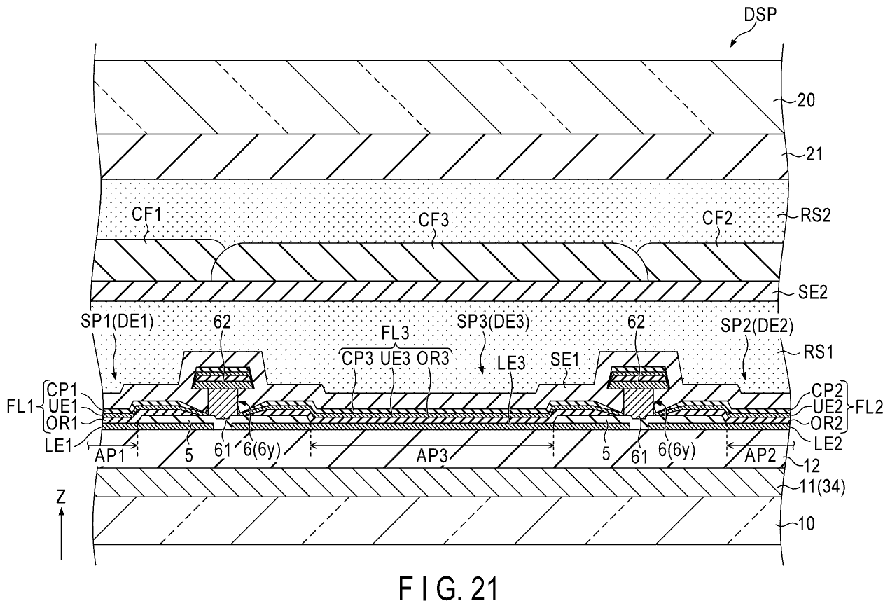

FIG. 21 is a schematic cross-sectional view of the display device DSP according to a sixth modified example. In the sixth modified example, the light-shielding layer BM is not provided in the boundaries of the color filters CF1, CF2 and CF3. FIG. 21 shows the structure of the display area DA. In the surrounding area SA, similarly, the light-shielding layer BM may not be provided.

The configurations of the first to sixth modified examples described above can be appropriately combined with each other. Further, the configurations of the first to sixth modified examples can be also applied to the other embodiments described below.

### Second Embodiment

A second embodiment is explained. The configurations which are not particularly referred to are the same as those of the first embodiment.

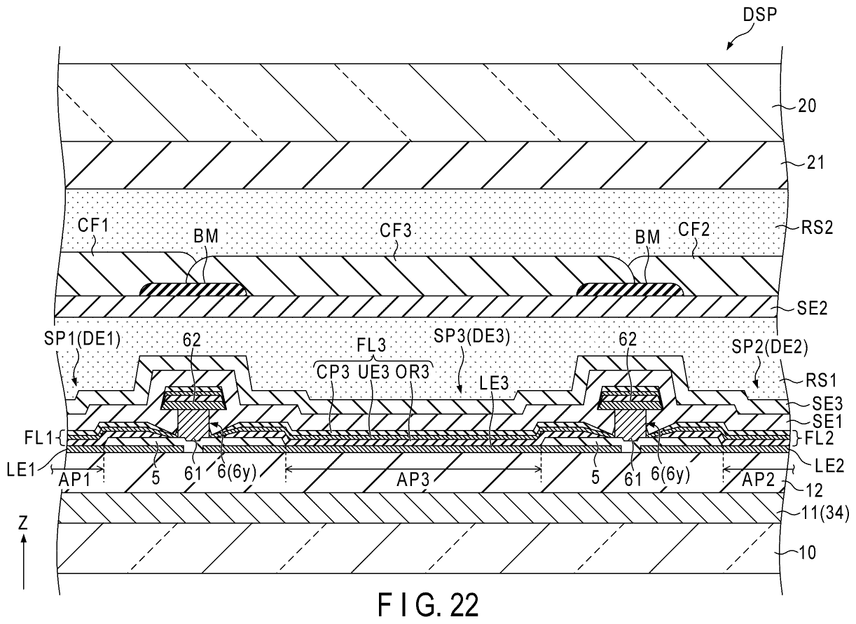

FIG. 22 is a schematic cross-sectional view showing the structure of the display area DA of a display device DSP according to the second embodiment. The display device DSP shown in FIG. 22 is different from the configuration of FIG. 3 in respect that the display device DSP further comprises a third sealing layer SE3.

The third sealing layer SE3 is provided between a first sealing layer SE1 and a first resin layer RS1. In the display area DA, the third sealing layer SE3 continuously covers the first sealing layer SE1. The third sealing layer SE3 can be formed of the same inorganic material as the first sealing layer SE1 and a second sealing layer SE2. The third sealing layer SE3 may be formed of a different type of inorganic material from the first sealing layer SE1 or the second sealing layer SE2.

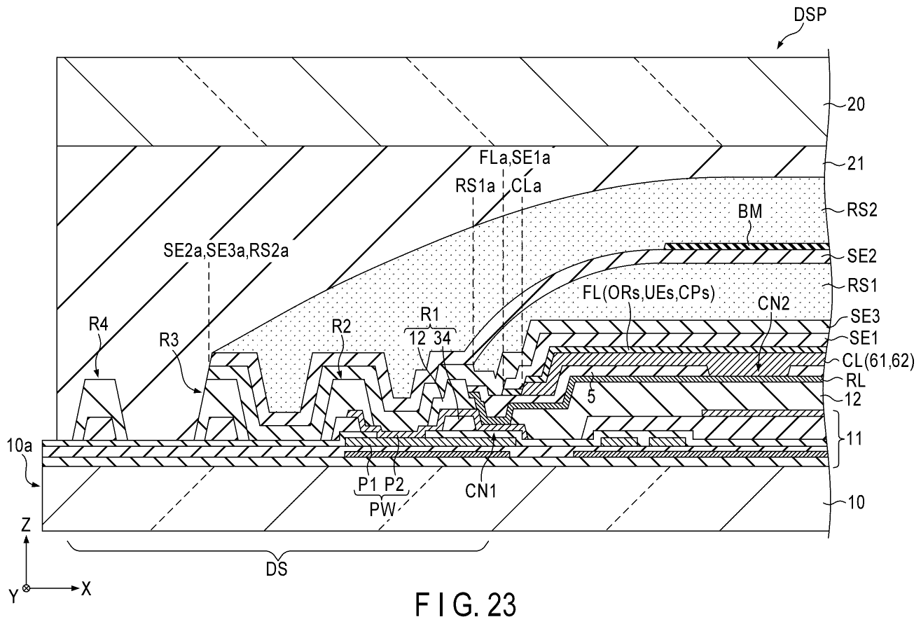

FIG. 23 is a schematic cross-sectional view showing the structure of the surrounding area SA of the display device DSP according to the second embodiment. In the surrounding area SA, similarly, the third sealing layer SE3 entirely covers the first sealing layer SE1. Further, the third sealing layer SE3 also covers part of a dam structure DS.

In the surrounding area SA, the second sealing layer SE2 covers, of the third sealing layer SE3, the portion exposed from the first resin layer RS1. An end portion RS1a of the first resin layer RS1 is covered with the second sealing layer SE2 and the third sealing layer SE3.

The second sealing layer SE2 and the third sealing layer SE3 are patterned by, for example, the method explained with reference to FIG. 10 to FIG. 14. In this case, like the example of FIG. 23, an end portion SE2a of the second sealing layer SE2, an end portion SE3a of the third sealing layer SE3 and an end portion RS2a of a second resin layer RS2 are aligned with each other.

Even in the configuration of the present embodiment, effects similar to those of the first embodiment can be obtained. Moreover, in the present embodiment, the first resin layer RS1 is entirely covered with the second and third sealing layers SE2 and SE3 each of which is formed of an inorganic material, thereby satisfactorily preventing moisture from entering the first resin layer RS1.

### Third Embodiment

A third embodiment is explained. The configurations which are not particularly referred to are the same as those of the first embodiment.

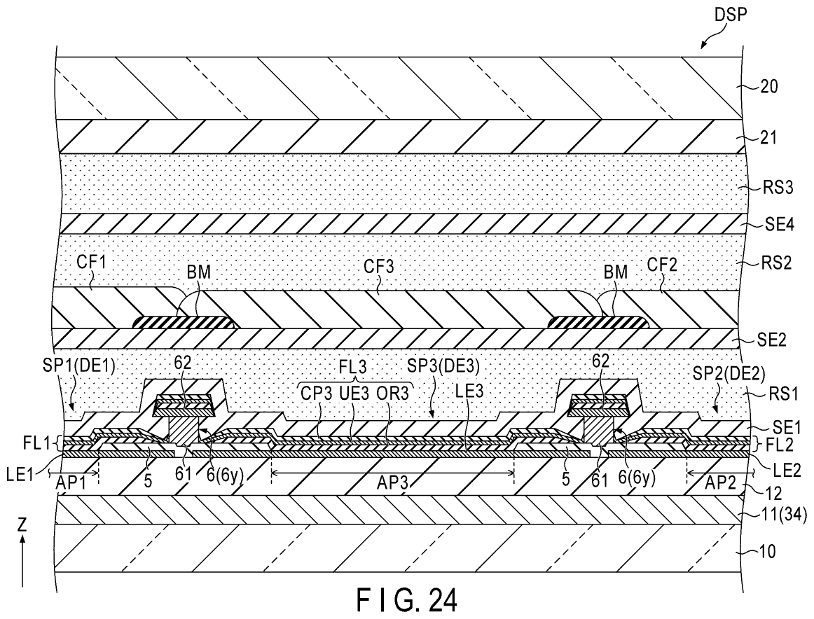

FIG. 24 is a schematic cross-sectional view showing the structure of the display area DA of a display device DSP according to the third embodiment. The display device DSP shown in FIG. 24 is different from the configuration of FIG. 3 in respect that the display device DSP further comprises a fourth sealing layer SE4 and a third resin layer RS3.

The fourth sealing layer SE4 covers a second resin layer RS2. The fourth sealing layer SE4 can be formed of the same inorganic material as a first sealing layer SE1 and a second sealing layer SE2. The fourth sealing layer SE4 may be formed of a different type of inorganic material from the first sealing layer SE1 or the second sealing layer SE2.

The third resin layer RS3 covers the fourth sealing layer SE4. For example, the third resin layer RS3 may be formed of the same resin material as a first resin layer RS1 and the second resin layer RS2 by an ink-jet method. A second substrate 20 is attached to the third resin layer RS3 by an adhesive layer 21.

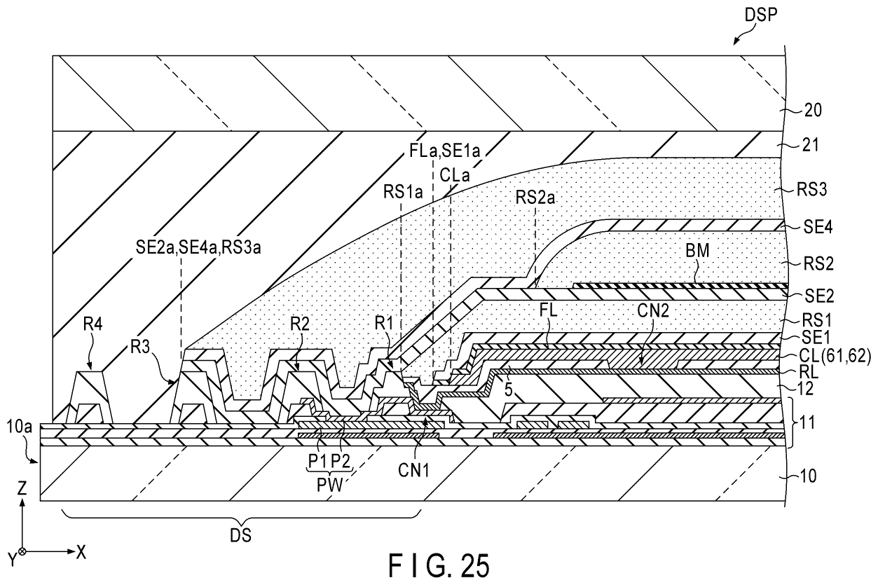

FIG. 25 is a schematic cross-sectional view showing the structure of the surrounding area SA of the display device DSP according to the third embodiment. In the surrounding area SA, similarly, the fourth sealing layer SE4 entirely covers the second resin layer RS2. Further, the fourth sealing layer SE4 covers, of the second resin layer RS2, the portion which covers a dam structure DS.

In the example of FIG. 25, an end portion RS2a of the second resin layer RS2 does not reach the dam structure DS. The end portion RS2a is covered with the second sealing layer SE2 and the fourth sealing layer SE4. An end portion RS3a of the third resin layer RS3 is located near a protrusion R3.

The second sealing layer SE2 and the fourth sealing layer SE4 are patterned by, for example, the method explained with reference to FIG. 10 to FIG. 14. However, in the present embodiment, the third resin layer RS3 functions as a mask at the time of the patterning. In this case, like the example of FIG. 25, an end portion SE2a of the second sealing layer SE2, an end portion SE4a of the fourth sealing layer SE4 and the end portion RS3a of the third resin layer RS3 are aligned with each other.

Even in the configuration of the present embodiment, effects similar to those of the first embodiment can be obtained. Further, in the present embodiment, the second resin layer RS2, color filters CF1, CF2 and CF3 and a light-shielding layer BM are provided in the area closed by the second and fourth sealing layers SE2 and SE4 formed of inorganic materials. Thus, it is possible to satisfactorily prevent moisture from entering the second resin layer RS2, the color filters CF1, CF2 and CF3 and the light-shielding layer BM. Moreover, as the third resin layer RS3 is provided in addition to the second resin layer RS2, the projections and depressions caused by the color filters CF1, CF2 and CF3 and the light-shielding layer BM are further satisfactorily planarized.

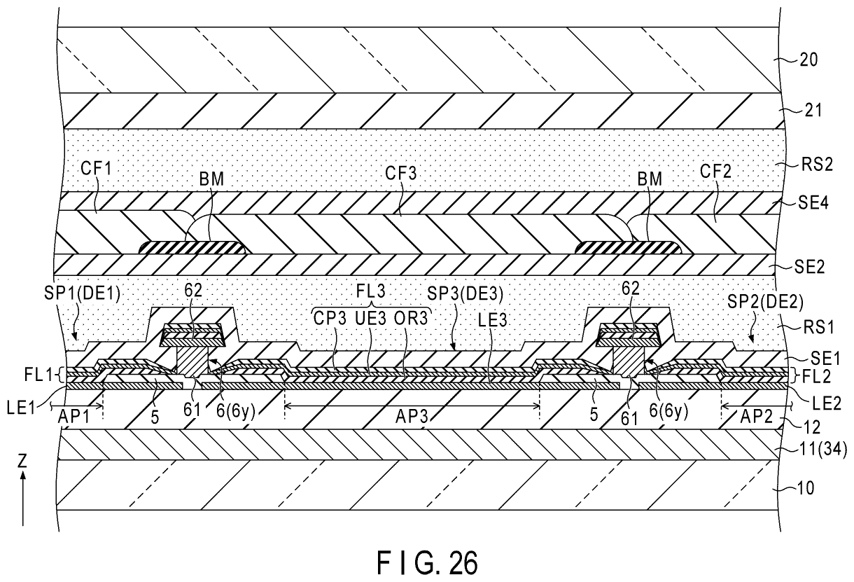

FIG. 26 is a schematic cross-sectional view showing a modified example of the display device DSP according to the present embodiment. In this modified example, the fourth sealing layer SE4 directly covers the color filters CF1, CF2 and CF3. Further, the second resin layer RS2 covers the fourth sealing layer SE4. This configuration can also satisfactorily prevent moisture from entering the color filters CF1, CF2 and CF3 and the light-shielding layer BM.

In the display device DSP shown in FIG. 24 to FIG. 26, the third sealing layer SE3 shown in the second embodiment may be further provided.

### Fourth Embodiment

A fourth embodiment is explained. The configurations which are not particularly referred to are the same as those of the first embodiment.

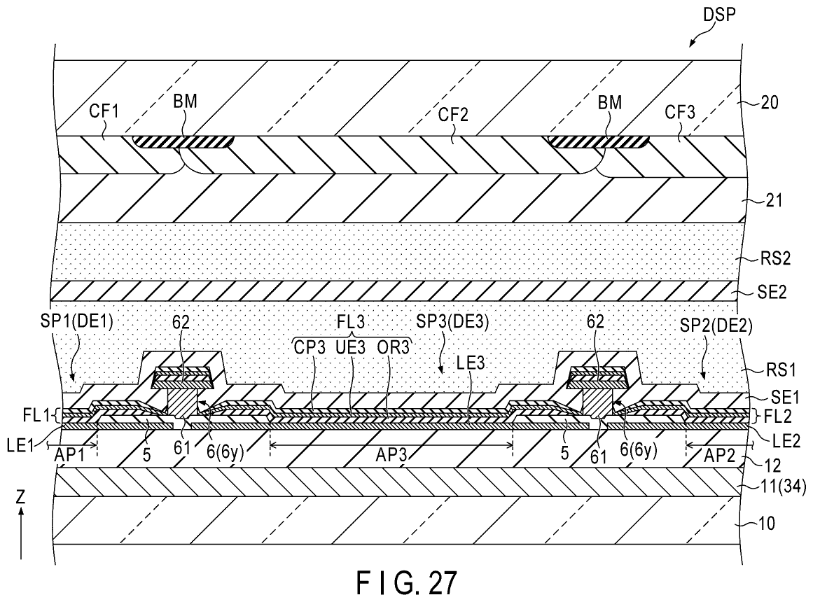

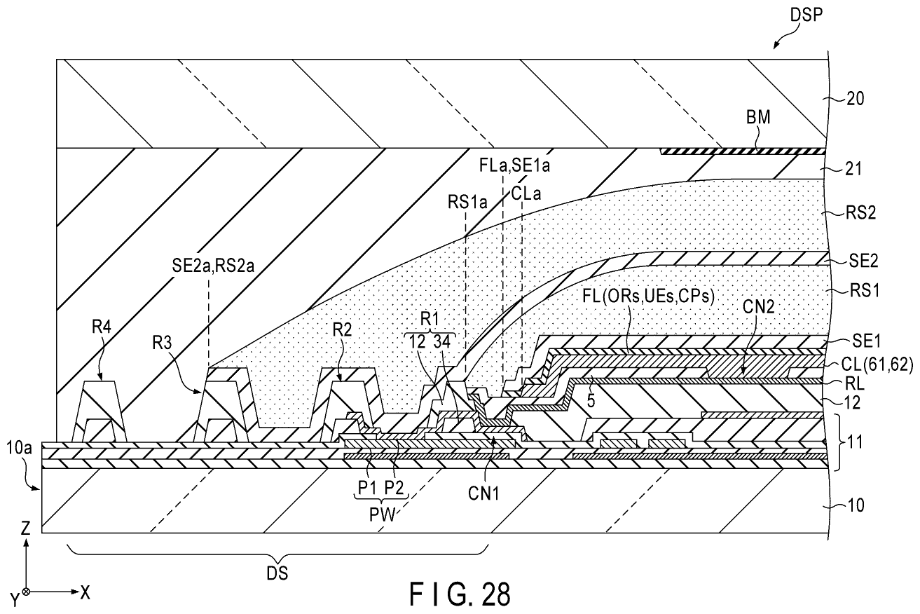

FIG. 27 is a schematic cross-sectional view showing the structure of the display area DA of a display device DSP according to the fourth embodiment. FIG. 28 is a schematic cross-sectional view showing the structure of the surrounding area SA of the display device DSP according to the fourth embodiment. The display device DSP shown in FIG. 27 and FIG. 28 is different from the configuration of FIG. 3 in respect that color filters CF1, CF2 and CF3 and a light-shielding layer BM are provided in a second substrate 20.

For example, the color filters CF1, CF2 and CF3 and the light-shielding layer BM are formed on the lower surface of the second substrate 20 (the surface facing a first substrate 10) and are covered with an adhesive layer 21. A sealing layer formed of an inorganic material may be provided between the color filters CF1, CF2 and CF3 or the light-shielding layer BM and the adhesive layer 21.

The second substrate 20 may include an optical element such as a polarizer, a protective film, a cover glass or a touchpanel. An optical element, a protective film, a cover glass or a touchpanel may be stacked in the second substrate 20. For example, an electrode, etc., constituting a touchpanel may be stacked in the second substrate 20, and a protective film or a cover glass may be provided on the stacked layer.

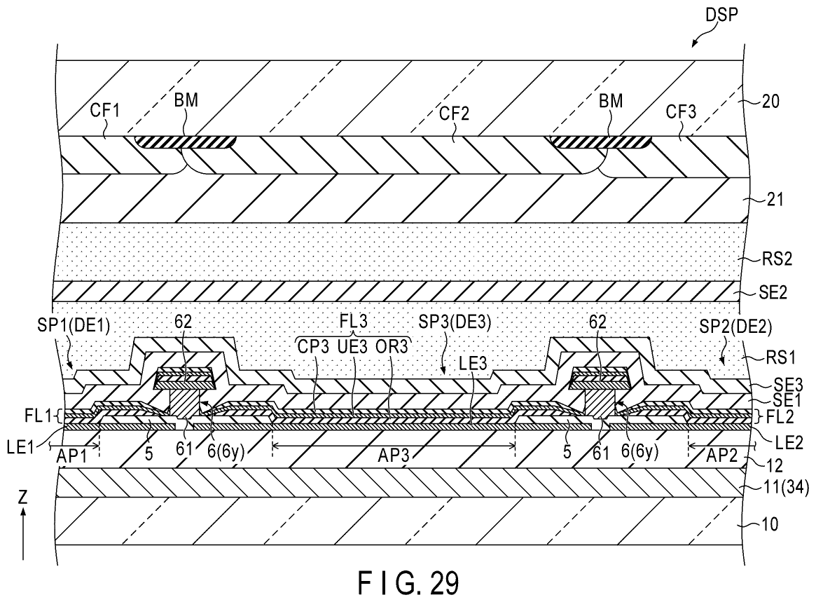

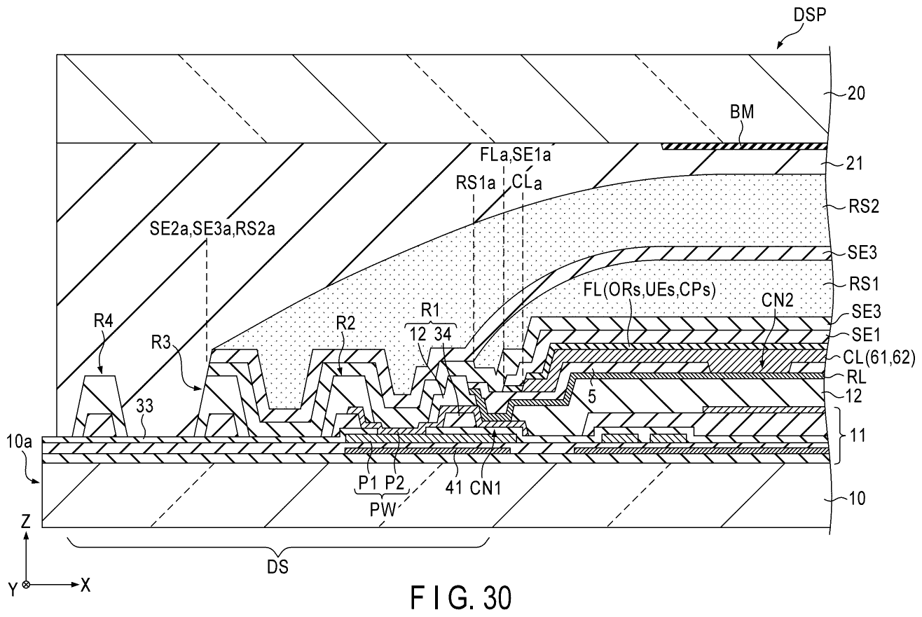

FIG. 29 and FIG. 30 are schematic cross-sectional views showing a modified example of the display device DSP according to the present embodiment. In this modified example, the display device DSP further comprises the third sealing layer SE3 shown in the second embodiment. The display device DSP may further comprise the fourth sealing layer SE4 and third resin layer RS3 shown in the third embodiment.

All of the display devices that can be implemented by a person of ordinary skill in the art through arbitrary design changes to the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
a lower electrode;
a rib comprising a pixel aperture which overlaps the lower electrode;
a partition including a conductive lower portion on the rib and an upper portion which protrudes from a side surface of the lower portion;
an organic layer which covers the lower electrode through the pixel aperture and emits light based on application of voltage;
an upper electrode which covers the organic layer and is in contact with the side surface of the lower portion;
a first sealing layer which is formed of an inorganic material and covers a display element including the lower electrode, the organic layer and the upper electrode;
a first resin layer located above the first sealing layer; and
a color filter which faces the display element via the first sealing layer and the first resin layer.

2. The display device of claim 1, further comprising a second sealing layer which is formed of an inorganic material and covers the first resin layer, wherein
the color filter is provided on the second sealing layer.

3. The display device of claim 2, further comprising a dam structure provided in a surrounding area around a display area including the display element, wherein
the dam structure includes a plurality of protrusions, and
the second sealing layer covers at least part of the protrusions.

4. The display device of claim 2, further comprising a third sealing layer formed of an inorganic material and located between the first sealing layer and the first resin layer, wherein
an end portion of the first resin layer is covered with the second sealing layer and the third sealing layer.

5. The display device of claim 2, further comprising a second resin layer which covers the color filter.

6. The display device of claim 5, further comprising a fourth sealing layer which is formed of an inorganic material and covers the second resin layer, wherein
an end portion of the second resin layer is covered with the second sealing layer and the fourth sealing layer.

7. The display device of claim 6, further comprising a third resin layer which covers the fourth sealing layer.

8. The display device of claim 1, further comprising:
a first substrate in which the lower electrode, the rib, the partition, the organic layer, the upper electrode and the first sealing layer are provided;
a second substrate in which the color filter is provided; and
an adhesive layer for attaching the first substrate and the second substrate to each other.

9. The display device of claim 1, further comprising a light-shielding layer which faces the partition via the first sealing layer and the first resin layer.

10. The display device of claim 9, further comprising:
a conductive layer provided in a surrounding area around a display area including the display element and connected to the partition;
a feed line provided in the surrounding area; and
a contact portion which connects the feed line and the conductive layer to each other, wherein
the light-shielding layer faces the contact portion.

11. A display device comprising:
a lower electrode;
a rib comprising a pixel aperture which overlaps the lower electrode;
a partition including a conductive lower portion on the rib and an upper portion which protrudes from a side surface of the lower portion;
an organic layer which covers the lower electrode through the pixel aperture and emits light based on application of voltage;
an upper electrode which covers the organic layer and is in contact with the side surface of the lower portion;
a first sealing layer which is formed of an inorganic material and covers display elements each including the lower electrode, the organic layer and the upper electrode;
a first resin layer located above the first sealing layer; and
a color filter which faces the display elements via the first sealing layer and the first resin layer, wherein
the partition surrounds the display elements.

12. The display device of claim 11, wherein
the organic layers of the display elements are divided by the partition.

13. The display device of claim 12, wherein
the first sealing layer continuously covers the organic layers of the display elements and the partition.

14. The display device of claim 11, wherein
the display elements include a first display element, a second display element and a third display element, and
the color filter includes a first color filter overlapping the first display element and having a first color, a second color filter overlapping the second display element and having a second color, and a third color filter overlapping the third display element and having a third color filter.

15. The display device of claim 14, wherein
the rib comprises a first pixel aperture which overlaps the first display element, a second pixel aperture which overlaps the second display element and a third pixel aperture which overlaps the third display element, and
sizes of the first pixel aperture, the second pixel aperture and the third pixel aperture are different from each other.

16. The display device of claim 14, further comprising a light-shielding layer provided in boundaries of the first color filter, the second color filter and the third color filter, wherein
the light-shielding layer faces the partition via the first sealing layer and the first resin layer.

17. The display device of claim 16, wherein
a width of the light-shielding layer is greater than a width of the partition.
